(19) United States
(12) Patent Application Publication
(10) Pub. No.: US 2020/0259119 A1
(43) Pub. Date: Aug. 13, 2020

(54) DISPLAY DEVICE

(71) Applicant: Samsung Display Co., Ltd., Yongin-city (KR)

(72) Inventors: HOYONG JUNG, Seongnam-si (KR); JISEOB KIM, Asan-si (KR); SANGIK HAN, Asan-si (KR)

(21) Appl. No.: 16/741,796

(22) Filed: Jan. 14, 2020

(30) Foreign Application Priority Data
Feb. 11, 2019 (KR) 10-2019-0015477

(51) Int. Cl. H01L 51/52; H01L 25/18; H01L 51/00; H01L 25/16

(52) U.S. Cl. CPC H01L 51/5253; H01L 25/167; H01L 51/0096; H01L 25/18

(57) ABSTRACT

A display device includes a base substrate including at a same side thereof: a first base portion having a first width along a first direction, and a second base portion which protrudes from the first base portion along a second direction crossing the first direction and has a second width along the first direction which is smaller than the first width; a display element layer disposed on the first base portion of the base substrate; an encapsulation layer which encapsulates the display element layer on the base substrate; and an electronic module which receives input from outside the display device or provides output from the display device to outside thereof, the electronic module corresponding to the second base portion and overlapped by the second base portion along a thickness direction of the display device which crosses each of the first direction and the second direction.

This application claims priority to Korean Patent Application No. 10-2019-0015477, filed on Feb. 11, 2019, and all the benefits accruing therefrom under 35 U.S.C. § 119, the contents of which are hereby incorporated by reference in its entirety.

### BACKGROUND

### 1. Field

The present disclosure relates to a display device having a narrow bezel.

### 2. Description of the Related Art

A display device includes various electronic parts, such as a display panel displaying an image, an input sensing member sensing an external input, and an electronic module. The electronic parts are electrically connected to each other by signal lines arranged in various ways. The display panel includes a light emitting device generating the image. The input sensing member includes sensing electrodes that sense the external input. The electronic module includes a camera, an infrared sensor, a proximity sensor, and the like.

### SUMMARY

One or more exemplary embodiment provides a display device having a narrow bezel.

Embodiments of the invention provide a display device including a base substrate including at a same side thereof: a first base portion having a first width along a first direction, and a second base portion which protrudes from the first base portion along a second direction crossing the first direction and has a second width along the first direction which is smaller than the first width; a display element layer disposed on the first base portion of the base substrate; an encapsulation layer which encapsulates the display element layer on the base substrate; and an electronic module which receives input from outside the display device or provides output from the display device to outside thereof, the electronic module corresponding to the second base portion and overlapped by the second base portion along a thickness direction of the display device which crosses each of the first direction and the second direction.

The first electronic module may be provided in plural as a plurality of electronic modules arranged along the same side of the base substrate, and a same one of the second base portion may correspond to and overlap each of the plurality of electronic modules.

The first electronic module may be provided in plural as a plurality of electronic modules arranged along the same side of the base substrate, and the plurality of electronic modules may include: a first electronic module corresponding to the second base portion and overlapped by the second base portion along the thickness direction of the display device, and a second electronic module different from the first electronic module, disposed spaced apart from an outer edge of the base substrate which is defined by the first base portion and the second base portion.

The first base portion has a first thickness, and the first thickness may be equal to a second thickness of the second base portion.

The first base portion has a first thickness, and the first thickness may be greater than a second thickness of the second base portion.

The first electronic module may be visible from outside the display device.

The first electronic module may overlap with the first base portion and the second base portion in a top plan view.

The base substrate may further include a third base portion which protrudes from the first base portion along the second direction, has a width along the first direction which is smaller than the first width, and is spaced apart from the second base portion along the first direction, the electronic module may be provided in plural as a plurality of electronic modules arranged along the same side of the base substrate, and the plurality of electronic modules may include: a first electronic module corresponding to the second base portion and overlapped by the second base portion along the thickness direction of the display device, and a second electronic module corresponding to the third base portion and overlapped by the third base portion along the thickness direction of the display device.

The encapsulation layer may overlap with the first base portion and be spaced apart from the second base portion in the top plan view.

The encapsulation layer may include a first encapsulation portion corresponding to the first base portion and a second encapsulation portion corresponding to the second base portion.

The second encapsulation portion may have a thickness which decreases as a distance from the first base portion increases.

An outer edge of the second base portion may have a curvature.

The second base portion may have a polygonal shape in the top plan view.

Embodiments of the invention provide a display device including a display panel including a base substrate including a first base portion and a second base portion which protrudes from a first side of the first base portion, along the first side, a boundary is defined between the first base portion and the second base portion, a length of the boundary being smaller than a length of the first side, a display element layer disposed on the first base portion of the base substrate, and an encapsulation layer which encapsulates the display element layer on the base substrate; and an electronic module which receives input from outside the display device or provides output from the display device to outside thereof, the electronic module corresponding to the second base portion and visible from outside the display device.

An edge of the encapsulation layer may correspond to the boundary.

The encapsulation layer may include a first encapsulation portion corresponding to the first base portion and a second encapsulation portion corresponding to the second base portion, the second encapsulation area may have a thickness which decreases as a distance from the first base portion increases, and a light transmittance area of the display panel may be defined including a planar area of the second base portion which corresponds to the electronic module and, a light transmittance of the light transmittance area being equal to or greater than about 90%.

The first base portion may have a thickness greater than a thickness of the second base portion.

The electronic module may overlap the boundary in a top plan view.

An outer edge of the encapsulation layer may not overlap with the boundary and the electronic module.

An outer edge of the second base portion may have a curvature or the second base portion may have a polygonal shape when in the top plan view.

According to one or more exemplary embodiment described above, the base substrate of the display device includes the first base portion and the second base portion which is protruded from the first base portion. The electronic module of the display device is disposed under the second base but is viewable from outside the display device. The base substrate of the display device may be provided as a separated portion of a mother substrate which is cut into plural separates base substrates. Although a cutting tolerance occurs in the cutting process for separating individual base substrates from the mother substrate, the electronic module under the base substrate is spaced apart from the active area by the predetermined distance, and the cutting tolerance does not cause the increase in the distance between the electronic module and the active area. Thus, increase of a width of a bezel of the display device owing to the cutting tolerance may be reduced or effectively prevented.

### BRIEF DESCRIPTION OF THE DRAWINGS

The above and other advantages of the present disclosure will become readily apparent by reference to the following detailed description when considered in conjunction with the accompanying drawings where:

FIG. 1 is a top plan view illustrating an exemplary embodiment of a display device;

FIGS. 2A to 2D are cross-sectional views respectively illustrating exemplary embodiments of display devices;

FIG. 3 is a cross-sectional view illustrating an exemplary embodiment of a display panel;

FIG. 4A is a top plan view illustrating an exemplary embodiment of a display panel;

FIG. 4B is an enlarged plan view illustrating portion AA′ of FIG. 4A;

FIG. 5 is a cross-sectional view taken along line I-I′ of FIG. 4A;

FIG. 6 is a cross-sectional view illustrating another exemplary embodiment of a display panel taken along line I-I′ shown in FIG. 4A;

FIG. 7 is a cross-sectional view illustrating still another exemplary embodiment of a display panel taken along line I-I′ shown in FIG. 4A;

FIG. 8 is an enlarged plan view illustrating another exemplary embodiment of portion AA′ shown in FIG. 4A;

FIG. 9 is an enlarged plan view illustrating still another exemplary embodiment of portion AA′ shown in FIG. 4A;

FIG. 10 is an enlarged plan view illustrating a modified exemplary embodiment of portion AA′ shown in FIG. 4A;

FIG. 11 is an enlarged plan view illustrating another modified exemplary embodiment of portion AA′ shown in FIG. 4A; and

FIG. 12 is an enlarged top plan view illustrating an exemplary embodiment of a base substrate relative to other components of a display panel.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element or layer is referred to as being related to another element such as being “on,” “connected to” or “coupled to” another element or layer, it can be directly on, connected or coupled to the other element or layer or intervening elements or layers may be present. In contrast, when an element or layer is referred to as being related to another element such as being “directly on,” “directly connected to” or “directly coupled to” another element or layer, no intervening elements or layers are present

Like numerals refer to like elements throughout. In the drawings, the thickness, ratio, and dimension of components are exaggerated for effective description of the technical content.

The terminology used herein is for the purpose of describing particular embodiments only and is not intended to be limiting. As used herein, the singular forms, “a”, “an” and “the” are intended to include the plural forms as well, unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath,” “below,” “lower,” “above,” “upper” and the like, may be used herein for ease of description to describe one element or feature's relationship to another element(s) or feature(s) as illustrated in the figures.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, the present disclosure will be explained in detail with reference to the accompanying drawings.

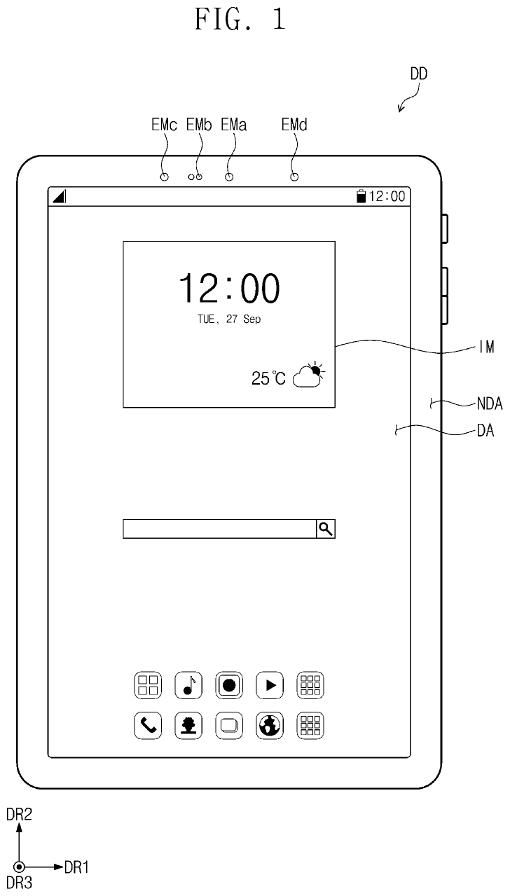

FIG. 1 is a top plan view illustrating an exemplary embodiment of a display device DD.

Referring to FIG. 1, the display device DD may be a device activated in response to an electrical signal. The display device DD may be employed in various electronic devices. In exemplary embodiments, for example, the display device DD may be applied to a relatively large-sized electronic device, such as a television, a display monitor or an outdoor billboard, and a relatively small and medium-sized electronic device, such as a personal computer, a notebook or tablet computer, a personal digital assistants, a car navigation unit, a game unit, a mobile electronic device and a camera. These are merely exemplary, and thus the display device DD may be applied to other electronic devices within the spirit and scope of the present disclosure. A tablet computer will be described as a representative example of the display device DD.

The display device DD may include a display area DA and a non-display area NDA. Light may be generated and/or emitted and/or an image IM may be generated and/or displayed at the display area DA. Light may not be generated and/or emitted and/or an image IM may not be displayed at the non-display area NDA. The non-display area NDA may be adjacent to the display area DA and may surround the display area DA.

The display device DD may include a surface (e.g., a display surface) that is substantially parallel to or disposed in a plane defined by a first direction DR1 and a second direction DR2 which cross each other. The display device DD may display an image IM at the display surface in a direction, e.g., a third direction DR3 which crosses each of the first direction DR1 and the second direction DR2. A thickness of the display device DD and components thereof may be defined along the third direction DR3. The image IM may include a motion image or a still image. FIG. 1 shows a clock window and icons as a representative example of the image IM.

In the exemplary embodiment, a front surface (or upper surface) and a rear surface (or lower surface) of each member of the display device DD are defined along a direction in which the image IM is displayed. The front and rear surfaces oppose each other along the third direction DR3, and a normal line direction relative to each of the front and rear surfaces is substantially parallel to the third direction DR3. Directions indicated by the first, second and third directions DR1, DR2 and DR3 are relative to each other, and thus the directions indicated by the first, second and third directions DR1, DR2 and DR3 may be changed to other directions. In the following descriptions, the expression “when viewed in a plan view” (or in a “top plan view”) may mean a view along the third direction DR3, e.g., in a direction normal to a plane in which the front surface and/or the rear surface is disposed. In addition, the expression “when viewed in a plan view” (or in a “top plan view”) may mean a view along a thickness or a thickness direction of the display device DD and/or various components thereof.

The display device DD may include a first electronic module EMa, a second electronic module EMb, a third electronic module EMc and a fourth electronic module EMd (e.g., first, second, third, and fourth electronic modules EMa, EMb, EMc, and EMd). The first electronic module EMa may be a camera module, the second electronic module EMb may be a proximity illuminance sensor module, the third electronic module EMc may be an infrared light emitting module, and the fourth electronic module EMd may be a light receiving module. The display device DD may further include a sound output module or a thermal sensing module in addition to the above electronic modules, however, the electronic modules are not limited thereto or thereby.

The first electronic module EMa may photograph an external image within an environment external to the display device DD. The second electronic module EMb may measure the illuminance and the proximity of the display device DD relative to an external environment, such as the measuring the illumination of an environment external to the display device DD or a distance of the display device DD relative to objects external to the display device DD. The third electronic module EMc may output an infrared light. The fourth electronic module EMd may sense the infrared light output from the third electronic module EMc which becomes an input to the fourth electronic module EMd from the environment external to the display device DD. That is, one or more of the electronic modules receives input from an environment external to the display device DD and/or transmits output from the display device DD to the environment external thereto. The input received from the environment may be processed by the display device DD, for example, to generate a photo image and/or determine the illuminance or the proximity described above.

The first electronic module EMa, the second electronic module EMb, the third electronic module EMc, and the fourth electronic module EMd are disposed in a periphery of the display area DA, and thus may be visible from outside the display device DD. The first electronic module EMa, the second electronic module EMb, the third electronic module EMc, and the fourth electronic module EMd may be disposed in the non-display area NDA. The non-display area NDA and/or the periphery of the display area DA may correspond to a bezel of the display device DD. In the top plan view, a width of the bezel may be defined along the plane defined by the first direction DR1 and the second direction DR2, taken from an outer edge of the display device DD toward an outer boundary of the display area DA. According to one or more exemplary embodiment of the present disclosure, respective distances between the electronic modules visible from outside the display device DD, and the display area DA may be reduced. Accordingly, a width of the bezel of the display device DD may be reduced. This will be described in detail later.

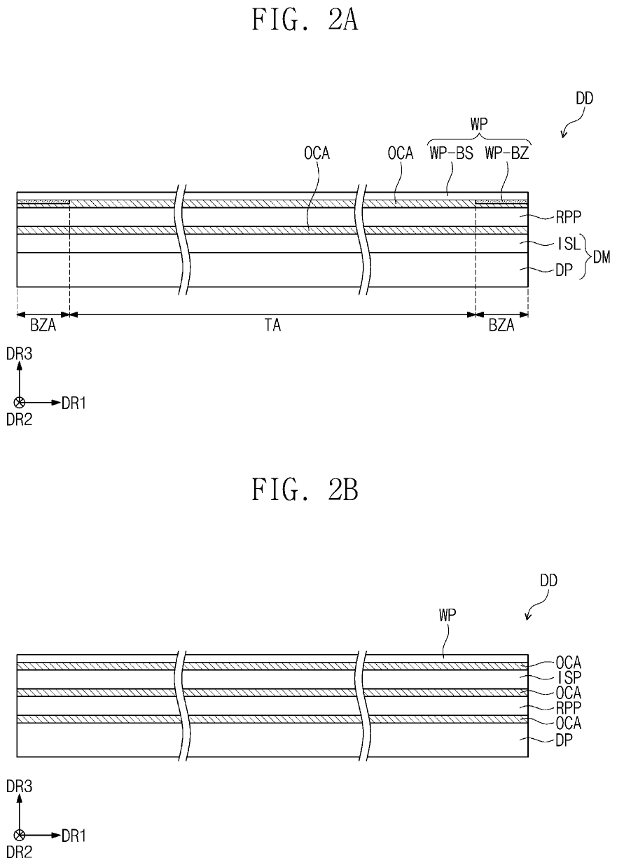

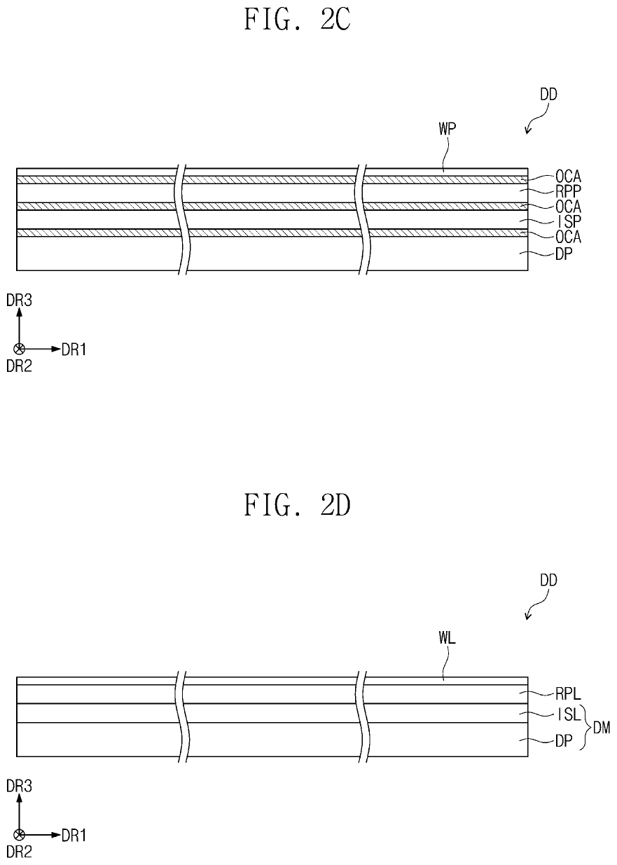

FIGS. 2A to 2D are cross-sectional views illustrating exemplary embodiments of display devices.

FIGS. 2A to 2D illustrate cross-sections defined by the first direction DR1 and the third direction DR3, and viewable along the second direction DR2. FIGS. 2A and 2D are illustrated in a simple manner to explain a stacking relationship of functional members of the display device DD.

The display device DD according to one or more exemplary embodiment of the present disclosure may include a display panel DP, an input sensing sensor, an anti-reflector and a window. The display device DD and/or a component thereof, such as the display panel DP, may include or define a pixel PX provided in plurality (e.g., plurality of pixels PX or pixels PX) at which light is generated, light is emitted and/or an image is displayed. The pixels PX may be provided in the display area DA.

In an exemplary embodiment of manufacturing the display device DD, at least some components among the display panel DP, the input sensing sensor, the anti-reflector and the window may be provided or formed through successive processes, or may be provided or formed separately from each other and subsequently attached to each other such as by an adhesive member. FIGS. 2A to 2D illustrate an optically clear adhesive (“OCA”) as a representative example of the adhesive member. The adhesive member described hereinafter may include a conventional adhesive or pressure sensitive adhesive.

In FIGS. 2A to 2D, among the input sensing sensor, the anti-reflector and the window, components provided or formed through the successive processes relative to other components are referred to as a “layer.” Among the input sensing sensor, the anti-reflector and the window, components separately provided and subsequently coupled to other components such as by the adhesive member are referred to as a “panel.” The panel includes a base layer providing a base surface, e.g., a synthetic resin film, a composite film or a glass substrate, however, the base layer may be omitted from the components referred to as the “layer.” In other words, the components referred to as the “layer” are disposed on the base surface provided by other components.

In one or more exemplary embodiment, a “layer” relative to another component within a display device DD may be coupled or attached to the component without using a separate bonding member, such as an adhesive. That is, the providing or forming of such “layer” on another component (e.g., via a manufacturing process, operation etc.) may impart a bond between the “layer” and the component such that the “layer” and the component are coupled or attached to each other. Such bond may be disposed at an interface of the “layer” and the component, and may be defined as a direct bond or a direct coupling (or direct attaching) relationship.

Throughout all sections of this disclosure, a component may be interchangeably referred to as a “layer” or “panel” described above, unless otherwise specified. An arrangement direction of layers or panels, e.g., a multi-layer structure, may be defined along a thickness direction of the display device DD. In one or more exemplary embodiment, for example, being provided or formed through successive processes and being coupled to other components, disposes respective layers and/or panels along a thickness direction of the display device DD.

Hereinafter, the input sensing sensor, the anti-reflector and the window may be respectively referred to as an “input sensing panel ISP”, an “anti-reflective panel RPP” and a “window panel WP” or as an “input sensing layer ISL”, an “anti-reflective layer RPL” and a “window layer WL” depending on the presence or absence of a base layer.

As illustrated in FIG. 2A, the display device DD may include the display panel DP, the input sensing layer ISL, the anti-reflective panel RPP, and the window panel WP. The input sensing layer ISL is directly disposed on the display panel DP. In the present disclosure, the expression “component “B” is directly disposed on component “A”” means that no intervening elements, such as an adhesive layer/an adhesive member, are present between the component “B” and the component “A.” In an exemplary embodiment of the expression “component “B” is directly disposed on component “A”, the component “B” is provided or formed on a base surface provided by the component “A” such as through successive processes after the component “A” is provided or formed.

The display panel DP and the input sensing layer ISL which is directly disposed on the display panel DP are defined together as a display module DM. The optically clear adhesive member OCA is disposed between the display module DM and the anti-reflective panel RPP and between the anti-reflective panel RPP and the window panel WP.

The display panel DP generates the image, and the input sensing layer ISL obtains coordinate information of an external input (e.g., touch event) to the display device DD and/or a component thereof. Although not shown separately, the display module DM according to the exemplary embodiment of the present disclosure may further include a protective member disposed on a lower surface of the display panel DP. The protective member and the display panel DP may be coupled to each other by the adhesive member. The display devices DD described hereinafter with reference to FIGS. 2B to 2D also may further include the protective member.

One or more exemplary embodiment of the display panel DP according to the exemplary embodiment of the present disclosure may be a light emitting type display panel, however, the display panel DP is not particularly limited. In one or more exemplary embodiment, for instance, the display panel DP may be an organic light emitting display panel or a quantum dot light emitting display panel which generates light therein and emits light therefrom. A light emitting layer of the organic light emitting display panel may include an organic light emitting material. A light emitting layer of the quantum dot light emitting display panel may include a quantum dot and a quantum rod. Hereinafter, the organic light emitting display panel will be described as a representative example of the display panel DP.

The window panel WP may form an outer surface or an external surface of the display device DD, without being limited thereto. The anti-reflective panel RPP reduces a reflectance of an external light incident thereto from outside the display device DD, e.g., from above the window panel WP. The anti-reflective panel RPP according to the exemplary embodiment of the present disclosure may include a retarder and/or a polarizer. The retarder may be a film type or liquid crystal coated type and may include a λ/2 retarder and/or a λ/4 retarder. The polarizer may be a film type and may include a stretched type synthetic resin film. The retarder and the polarizer may further include a protective film. The retarder and/or the polarizer or the protective film may be defined as a base layer of the anti-reflective panel RPP.

The anti-reflective panel RPP according to the exemplary embodiment of the present disclosure may include color filters. The color filters may have a predetermined arrangement. The arrangement of the color filters may be determined by taking into account emission colors of pixels PX included in the display panel DP. The anti-reflective panel RPP may further include a black matrix disposed adjacent to the color filters.

The anti-reflective panel RPP according to the exemplary embodiment of the present disclosure may include a destructive interference structure. In an exemplary embodiment, for instance, the destructive interference structure may include a first reflection layer and a second reflection layer, which are disposed in different layers from each other along a thickness of the anti-reflective panel RPP. A first reflection light and a second reflection light, which are reflected by the first reflection layer and the second reflection layer, respectively, may be destructively interfered, and thus the reflectance of the external light may be reduced.

The window panel WP according to the exemplary embodiment of the present disclosure includes a base substrate WP-BS and a light shielding pattern WP-BZ. The base substrate WP-BS may include a glass substrate and/or a synthetic resin film. The base substrate WP-BS is not limited to a single-layer structure. The base substrate WP-BS may include two or more films coupled to each other such as by the adhesive member.

The light shielding pattern WP-BZ partially overlaps with the base substrate WP-BS. The light shielding pattern WP-BZ is disposed on a rear surface of the base substrate WP-BS and substantially defines or corresponds to a bezel area BZA of the display device DD. The bezel area BZA may substantially define or correspond to the bezel of the display device DD discussed above. A planar area in which the light shielding pattern WP-BZ is not disposed (e.g., a planar area of the display device DD which excludes the light shielding pattern WP-BZ) defines or corresponds to the transmissive area TA of the display device DD. The transmissive area TA corresponds to the display area DA of FIG. 1, and the bezel area BZA corresponds to the non-display area NDA of FIG. 1. In the window panel WP, a planar area in which the light shielding pattern WP-BZ is disposed is defined as a light shielding area of the window panel WP, and the planar area in which the light shielding pattern WP-BZ is not disposed (e.g., a planar area of the window panel WP which excludes the light shielding pattern WP-BZ) is defined as a transmissive area of the window panel WP.

The light shielding pattern WP-BZ may have a multi-layer structure. The multi-layer structure may include a colored layer and a black light shielding layer. The colored layer and the black light shielding layer may be provided or formed through a deposition, printing, or coating process. Although not shown in figures, the window panel WP may further include a functional coated layer disposed on an entire surface of the base substrate WP-BS. The functional coated layer may include an anti-fingerprint layer, an anti-reflective layer, and a hard coated layer. In FIGS. 2B to 2D, the window panel WP and the window layer WL are schematically shown without separating the base substrate WP-BS from the light shielding pattern WP-BZ, but may each include the base substrate WP-BS and the light shielding pattern WP-BZ as described above.

As illustrated in FIGS. 2B and 2C, the display device DD may include a display panel DP, an input sensing panel ISP, an anti-reflective panel RPP, and a window panel WP. A stacking order of the input sensing panel ISP and the anti-reflective panel RPP may be variously changed as illustrated in FIGS. 2B and 2C.

As illustrated in FIG. 2D, the display device DD may include a display panel DP, an input sensing layer ISL, an anti-reflective layer RPL, and a window layer WL. As compared with the display device DD shown in FIG. 2A, the optically clear adhesive members OCA are omitted since the input sensing layer ISL, the anti-reflective layer RPL, and the window layer WL are each provided or formed on a base surface provided by the display panel DP, such as through successive processes in a method of manufacturing the display device DD. A stacking order of the input sensing layer ISL and the anti-reflective layer RPL may be variously changed.

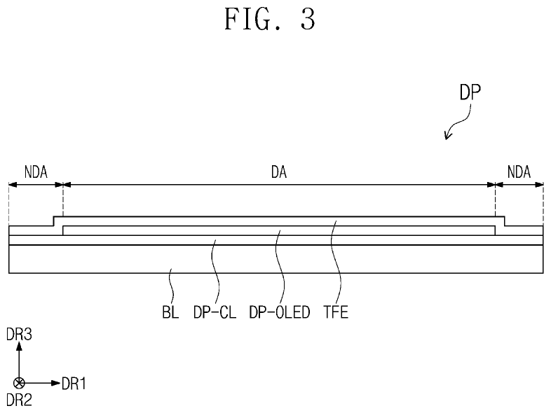

FIG. 3 is a cross-sectional view illustrating an exemplary embodiment of a display panel DP. FIG. 3 illustrates a cross-section defined by the first direction DR1 and the third direction DR3.

Referring to FIG. 3, the display panel DP includes a base substrate BL, a circuit element layer DP-CL, a display element layer DP-OLED, and an encapsulation layer TFE. Although not shown separately, the display panel DP may further include functional layers, such as an anti-reflective layer and a refractive index control layer.

The base substrate BL may be a stacked structure including a glass substrate, a silicon substrate, a plastic substrate, an insulating film or a plurality of insulating layers.

The circuit element layer DP-CL may be disposed on the base substrate BL. The circuit element layer DP-CL includes at least one insulating layer and a circuit element. Hereinafter, the insulating layer included in the circuit element layer DP-CL will be referred to as an “intermediate insulating layer.” The intermediate insulating layer includes at least one intermediate inorganic layer and at least one intermediate organic layer. The circuit element includes a signal line (e.g., conductive signal line) and a driving circuit of a pixel PX. The driving circuit may be connected to the signal line. An electrical signal may be transmitted through the signal line, to the pixel PX. The display device DD, the pixel PX or a component thereof may be activated in response to the electrical signal. The electrical signal may include, but is not limited to, a gate signal, a data or image signal, a power signal, a control signal, a driving signal, a timing signal, etc.

In one or more exemplary embodiment, the circuit element layer DP-CL may be provided or formed by coating and depositing processes used to form an insulating layer, a semiconductor layer and a conductive layer and a patterning process used to pattern the insulating layer, the semiconductor layer and the conductive layer.

The display element layer DP-OLED may be disposed on the circuit element layer DP-CL. The display element layer DP-OLED may be connected to the circuit element layer DP-CL. The display element layer DP-OLED includes a light emitting element. The display element layer DP-OLED may include organic light emitting diodes. The display element layer DP-OLED may further include an organic layer such as a pixel definition layer.

The encapsulation layer TFE is disposed on the display element layer DP-OLED to encapsulate the display element layer DP-OLED. The encapsulation layer TFE includes at least one insulating layer. The encapsulation layer TFE according to the exemplary embodiment of the present disclosure may include at least one inorganic layer (hereinafter, referred to as an “encapsulation inorganic layer”). The encapsulation layer TFE according to the exemplary embodiment of the present disclosure may include at least one organic layer (hereinafter, referred to as an “encapsulation organic layer”) and at least one encapsulation inorganic layer.

The encapsulation inorganic layer protects the display element layer DP-OLED from moisture and/or oxygen, and the encapsulation organic layer protects the display element layer DP-OLED from a foreign substance, e.g., a dust particle. The encapsulation inorganic layer may include a silicon nitride layer, a silicon oxynitride layer, a silicon oxide layer, a titanium oxide layer, or an aluminum oxide layer, however, is not limited thereto or thereby. The encapsulation organic layer may include an acrylic-based organic layer, however, is not particularly limited.

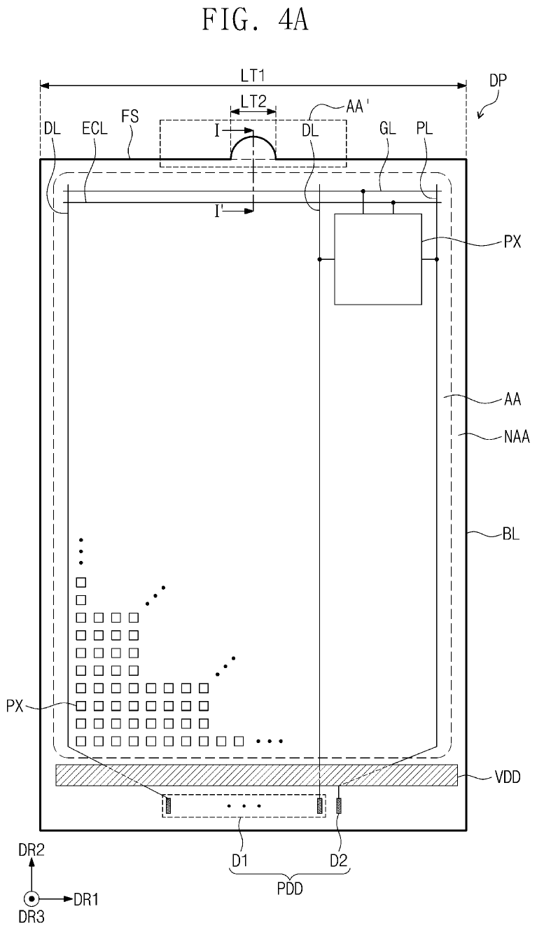

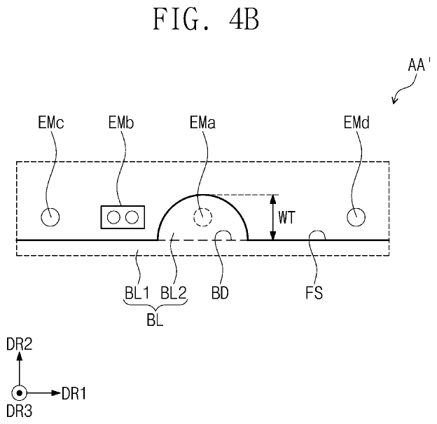

FIG. 4A is a top plan view illustrating an exemplary embodiment of a display panel DP. FIG. 4B is an enlarged top plan view illustrating portion AA′ of FIG. 4A.

Referring to FIGS. 4A and 4B, the display panel DP may include a base substrate BL, a plurality of pixels PX, a plurality of signal lines GL, DL, PL, and ECL, and a plurality of display pads PDD. The signal lines GL, DL, PL, and ECL and the display pads PDD may form the circuit element layer DP-CL (refer to FIG. 3), and the pixels PX may form the display element layer DP-OLED (refer to FIG. 3).

An active area AA of the display panel DP may be a planar area at which the image is displayed, and a peripheral area NAA may be a planar area in which a driving circuit and/or a driving line which is connected to the active area AA is disposed. FIG. 4A illustrates the active area AA and the peripheral area NAA of the display panel DP. The active area AA may correspond to the display area DA of FIG. 1, and the peripheral area NAA may correspond to the non-display area NDA of FIG. 1. That is, the peripheral area NAA of FIG. 4A corresponds to the bezel of the display device DD, and arrangement of components of the display panel DP within the peripheral area contributes directly to a size or dimension of the bezel of the display device DD.

The base substrate BL may include a first base portion BL1 and a second base portion BL2. The first base portion BL1 may be a planar area included in the active area AA, and the second base portion BL2 may be a planar area included in the peripheral area NAA (e.g., outside of the active area AA). As shown in FIG. 4A, a portion of the first base portion BL1 may be outside the active area AA to be disposed in the peripheral area NAA.

The second base portion BL2 may protrude from the first base portion BL1. In one or more exemplary embodiment, for example, the second base portion BL2 may protrude along the second direction DR2, from a first side FS of the first base portion BL1 which lengthwise extends along the first direction DR1.

The first base portion BL1 may have a first width LT1 greater than a second width LT2 of the second base portion BL2. A widthwise direction of the first width LT1 and a widthwise direction of the second width LT2 may be substantially parallel to the first direction DR1. The first width LT1 may be defined as a maximum width of the first base portion BL1, and the second width LT2 may be defined as a maximum width of the second base portion BL2. A length of a boundary BD between the first base portion BL1 and the second base portion BL2 may correspond to the second width LT2. That is, the length of the boundary BD may be smaller than a length of the first side FS. The boundary BD may correspond to a virtual line extension of the first side FS. A first edge of the base substrate BL may include or be defined by the first side FS together with the second base portion BL2.

The first electronic module EMa may be disposed under the second base portion BL2. That is, the second base portion BL2 may be closer to a viewing side of the display device DD than the first electronic module EMa. The first electronic module EMa may overlap with the second base portion BL2 when viewed in a plan view. The second electronic module EMb, the third electronic module EMc, and the fourth electronic module EMd except for the first electronic module EMa, may not overlap with the second base portion BL2. The second electronic module EMb, the third electronic module EMc, and the fourth electronic module EMd may be spaced apart from the second base portion BL2 in the plan view.

The base substrate BL may be a portion of a mother substrate. In an exemplary embodiment of a method of manufacturing a display device, the base substrate BL may be provided or formed by cutting one mother substrate to separate a portion thereof from a remainder of the mother substrate. That is, the base substrate BL may be a separated portion of the cut mother substrate. The first base portion BL1 and the second base portion BL2 may be portions of a same base substrate BL which has been separated from a reminder of the mother substrate. In the exemplary embodiment of the present disclosure, the mother substrate may be, but not limited to, a glass substrate.

In an exemplary embodiment of a method of manufacturing a display device, a wheel cutting method or a laser cutting method may be applied to cut the mother substrate. A cutting tolerance may exist for each of the wheel cutting and laser cutting methods. The cutting tolerance may be about ±50 micrometers. In an exemplary embodiment, for example, when assuming that a distance from an outer edge of the encapsulation layer TFE (refer to FIG. 3) to an outer edge of the base substrate BL is about 150 micrometers along the first direction DR1, the distance from an outer edge of the encapsulation layer TFE (refer to FIG. 3) to an outer edge of the base substrate BL provided or formed by the wheel cutting and laser cutting methods may be in a range from about 100 micrometers to about 200 micrometers due to the cutting tolerance.

According to a comparison embodiment of the present disclosure, an electronic module such as the camera module may be disposed outside of the base substrate BL. That is, the camera module and the base substrate BL may not overlap with each other when viewed in a plan view. When the distance increases as the cutting tolerance increases, a distance between the camera module and the active area AA may increase, and this may cause a dead space, e.g., an increase in width of the bezel.

However, according to one or more exemplary embodiment of the present disclosure, the first electronic module EMa is disposed under the base substrate BL, e.g., overlapping the base substrate BL along a thickness direction thereof. That is, the first electronic module EMa may be disposed within a planar area of the base substrate BL and in consideration of only a distance from the active area AA when viewed in a plan view. Accordingly, a problem that the first electronic module EMa is disposed at an increased distanced from the active area AA due to the increase of the cutting tolerance may be solved.

According to the exemplary embodiment of the present disclosure, the second base portion BL2 may be disposed only in the area in which the first electronic module EMa is disposed. Accordingly, a space in which electronic modules such as a speaker are disposed may be secured in an area, in which the second base portion BL2 is not disposed, facing the first side FS of the first base portion BL1.

A length WT in the second direction DR2 of the second base portion BL2 may be greater than a total dimension or size of the first electronic module EMa. An outer edge or outer portion of the second base portion BL2 may have a curvature, and the length WT of the second base portion BL2 may be a maximum width of the second base portion BL2 relative to the first side FS.

The pixels PX, the signal lines GL, DL, PL, and ECL, and the display pads PDD may be disposed on the base substrate BL.

The pixels PX may be disposed in the active area AA. The signal lines GL, DL, PL, and ECL are connected to the pixels PX to transmit electrical signals to the pixels PX and control and/or drive the pixels to generate light, to emit light and/or to display an image IM. Among the signal lines included in the display panel DP, a scan line GL provided in plurality (e.g., scan lines GL), a data line DL provided in plurality (e.g., data lines DL), one or more of a power line PL (e.g., power lines PL), and one or more of a light emitting control line ECL (e.g., light emitting control lines ECL) are shown as a representative example. The signal lines GL, DL, PL, and ECL may further include an initialization voltage line, however, are not be limited to a particular example.

A power pattern VDD is disposed in the peripheral area NAA. In the present exemplary embodiment, the power pattern VDD is connected to a plurality of power lines PL. As described above, the display panel DP includes the power pattern VDD, and thus the pixels may receive the same power signal which is transmitted through the power pattern VDD.

The display pads PDD may include a first pad D1 and a second pad D2. The first pad D1 may be provided in a plural number, (e.g., first pads D1) and the first pads D1 may be respectively connected to the data lines DL. The second pad D2 may be connected to the power pattern VDD to be electrically connected to the power line PL. The display panel DP may apply the electrical signals, which are provided from outside the display panel DP, through the display pads PDD and to the pixels PX. The display pads PDD may further include pads to receive other electrical signals in addition to the first and second pads D1 and D2 and are not limited to a particular embodiment.

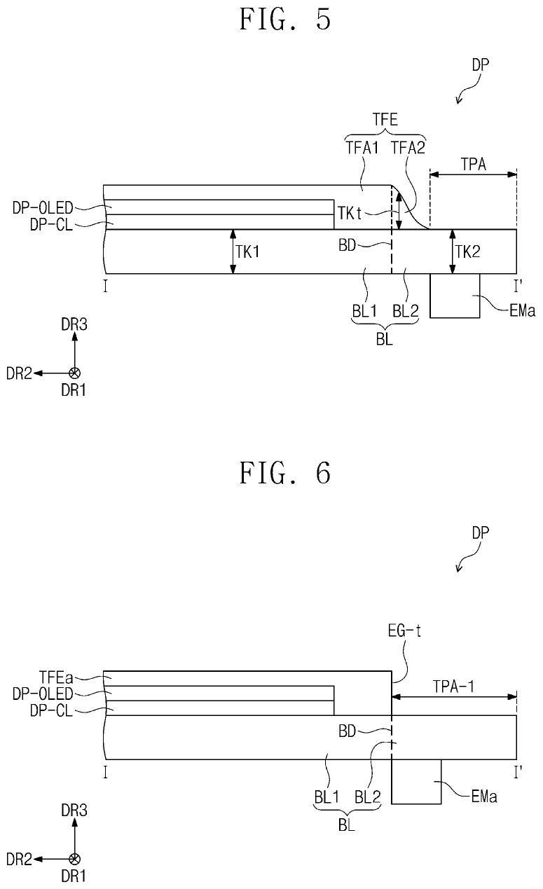

FIG. 5 is a cross-sectional view of the display panel DP taken along line I-I′ of FIG. 4A.

Referring to FIG. 5, the encapsulation layer TFE may include a first encapsulation area TFA1 (e.g., a first encapsulation portion TFA1) and a second encapsulation area TFA2 (e.g., a second encapsulation portion TFA2). The first encapsulation area TFA1 may be a planar area at which a portion of the encapsulation layer TFE is disposed on the first base portion BL1, and the second encapsulation area TFA2 may be a planar area different from the first encapsulation area TFA1 and at which a portion of the encapsulation layer TFE is disposed on the second base portion BL2.

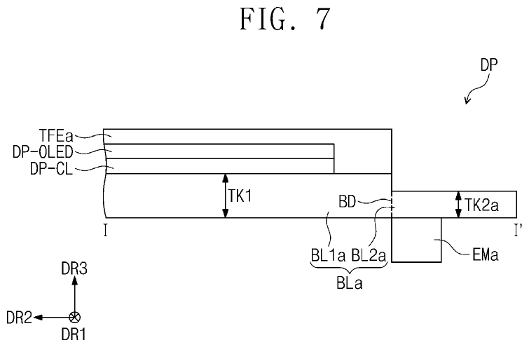

A thickness (TK1 in FIG. 7) of the first base portion BL1 may be the same as a thickness of the second base portion BL2, without being limited thereto. The second encapsulation area TFA2 may have a thickness TKt that gradually decreases as a distance along the second direction DR2 from the first base portion BL1 increases. The second encapsulation layer TFA2 may be referred to as a “shadow area.” FIG. 5 shows only the second encapsulation area TFA2, however, a residual layer of the display element layer DP-OLED and a residual layer of the circuit element layer DP-CL may be further disposed under the second encapsulation area TFA2, e.g., between the encapsulation layer TFE and the base substrate BL at the second base portion BL2. A light transmittance of the display panel DP may be reduced due to the second encapsulation area TFA2 and the residual layers.

A remaining planar area of the second base portion BL2 at which the second encapsulation layer TFA2 is not disposed, may define a transmissive area TPA of the second base portion BL2. According to the exemplary embodiment of the present disclosure, the first electronic module EMa may be disposed to overlap with the transmissive area TPA of the second base portion BL2, in which a transmittance of the display panel DP is equal to or greater than about 90% and equal to or smaller than about 100%. Therefore, degradation of a performance of the first electronic module EMa may be reduced or effectively prevented.

FIG. 6 is a cross-sectional view illustrating another embodiment of a display panel DP taken along line I-I′ shown in FIG. 4A.

Referring to FIG. 6, all residual layers (e.g., of the display element layer DP-OLED and/or the circuit element layer DP-CL discussed above) which remain disposed on a second base portion BL2 in manufacturing the display device DD may be removed. A mask process using a photoresist pattern may be further executed to remove the residual layers. In an exemplary embodiment of a method of manufacturing a display device, for example, the second encapsulation area TFA2 shown in FIG. 5 may be omitted since the residual layers described above are removed from the second base portion BL2. In addition, the residual layer of the display element layer DP-OLED and the residual layer of the circuit element layer DP-CL, which are disposed under the second encapsulation area TFA2, may be removed together, that is, in a same process and/or at a same time within the method of manufacturing the display device.

An edge EG-t of an encapsulation layer TFEa may correspond to (e.g., be aligned with) a boundary BD between a first base portion BL1 and the second base portion BL2. Since the second encapsulation area TFA2 and the residual layers are removed, a light transmittance of a transmissive area TPA-1 of the display panel DP including the second base portion BL2 may be about 90% or more. Thus, the first electronic module EMa may be disposed as close as possible to the boundary BD.

As illustrated in FIG. 6, an entire length of the second base portion BL2 along the second direction DR2 may define the transmissive area TPA-1 of the display panel DP at which the first electronic module EMa is disposed. As the first electronic module EMa being disposed as close as possible to the boundary BD, an edge of the first electronic module EMa may correspond to the edge EG-t of then encapsulation layer TFEa and/or the boundary BD between the first base portion BL1 and the second base portion BL2

FIG. 7 is a cross-sectional view illustrating still another exemplary embodiment of a display panel taken along line I-I′ shown in FIG. 4A.

Referring to FIG. 7, a base substrate BLa may include a first base portion BL1a and a second base portion BL2a. The first base portion BL1a may have a thickness TK1 greater than a second thickness TK2a of the second base portion BL2a. That is, a thickness TK1 of the base substrate BLa at the first base portion BL1 thereof, may be greater than a thickness TK2a of the base substrate BLa at the second base portion BL2 thereof. A reduced-thickness portion of the base substrate BLa may define the second base portion BL2, without being limited thereto. Such reduced-thickness portion of the base substrate BLa may define a transmissive area TPA (or transmissive area TPA-1), without being limited thereto.

In an exemplary embodiment of a method of manufacturing a display device, a portion of the base substrate BLa may be removed at the second base portion BL2a along a thickness direction such as by following a process of removing a residual layer of the encapsulation layer TFEa, a residual layer of the display element layer DP-OLED, and a residual layer of the circuit element layer DP-CL, which are disposed on the second base portion BL2a and a portion of the base substrate BLa. Accordingly, a light transmittance of the second base portion BL2a may be higher than a light transmittance of the first base portion BL1a, owing to a difference in thicknesses thereof.

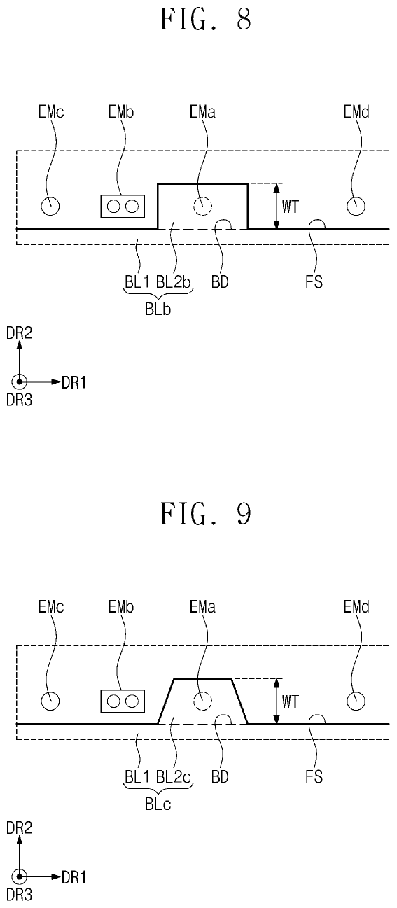

FIG. 8 is an enlarged plan view illustrating another exemplary embodiment of portion AA′ shown in FIG. 4A.

Referring to FIG. 8, a base substrate BLb may include a first base portion BL1 and a second base portion BL2b. The second base portion BL2b may protrude from the first base portion BL1. The second base portion BL2b may have a quadrangular shape when viewed in a plan view.

FIG. 9 is an enlarged plan view illustrating still another exemplary embodiment of portion AA′ shown in FIG. 4A.

Referring to FIG. 9, a base substrate BLc may include a first base portion BL1 and a second base portion BL2c. The second base portion BL2c may protrude from the first base portion BL1. The second base portion BL2c may have a trapezoid shape when viewed in a plan view. In the exemplary embodiment of the present disclosure, the planar shape of the second base portion BL2c is not limited to the planar shapes described with reference to FIGS. 4, 8 and 9.

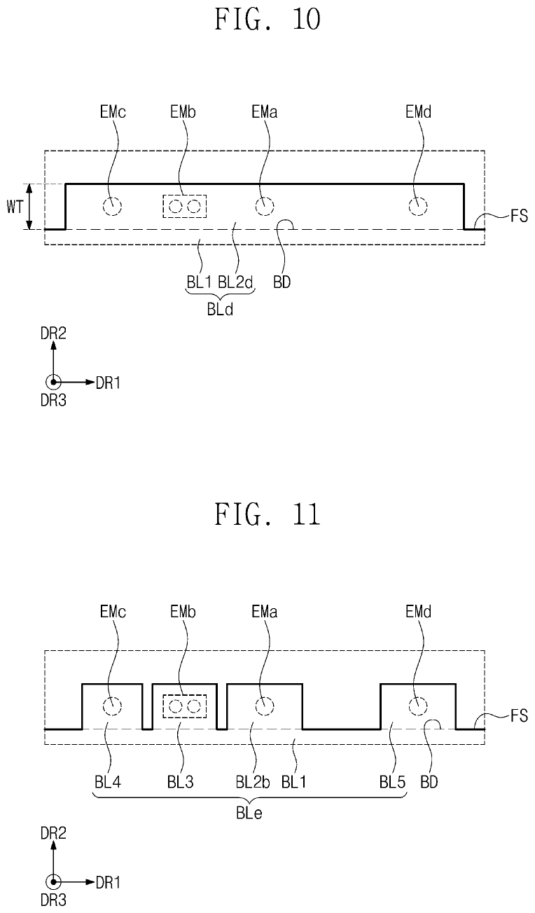

FIG. 10 is an enlarged plan view illustrating a modified exemplary embodiment of portion AA′ shown in FIG. 4A.

Referring to FIG. 10, a base substrate BLd may include a first base portion BL1 and a second base portion BL2d. The second base portion BL2d may protrude from the first base portion BL1. The second base portion BL2d may be a single protrusion of the base substrate BLd at the first side FS of the base substrate BLd.

The first, second, third, and fourth electronic modules EMa, EMb, EMc, and EMd may be disposed under the second base portion BL2d. That is, a same single one second base portion BL2d corresponds to each of the first, second, third, and fourth electronic modules EMa, EMb, EMc, and EMd. Accordingly, the second base portion BL2d may overlap with the first, second, third, and fourth electronic modules EMa, EMb, EMc, and EMd when viewed in a plan view.

According to the exemplary embodiment of the present disclosure, the first, second, third, and fourth electronic modules EMa, EMb, EMc, and EMd may be visible from outside the display device DD as shown in FIG. 1. Since the first, second, third, and fourth electronic modules EMa, EMb, EMc, and EMd overlap with the same single one of the second base portion BL2d, respective distances between the active area AA (refer to FIG. 4A), and each of the first, second, third, and fourth electronic modules EMa, EMb, EMc, and EMd may not increase even though a length WT of the second base portion BL2d increases along the second direction DR2.

The light shielding pattern WP-BZ (refer to FIG. 2A) overlapping with the first, second, third, and fourth electronic modules EMa, EMb, EMc, and EMd may be provided with openings defined therethrough along the thickness direction of a material layer or material panel from which the light shielding pattern WP-BZ is provided or formed. The openings may be defined by removing portions of the material layer or the material panel to provide or form the openings in the light shielding pattern WP-BZ. The first, second, third, and fourth electronic modules EMa, EMb, EMc, and EMd may be visible from outside the display device DD at the openings. Where the openings penetrate through the thickness of the material layer or the material panel, an electronic module corresponding to an opening may be exposed to outside the display device DD at the opening, and light, sound, etc. may be transmitted through the opening to and/or from the electronic module.

Different from the exemplary embodiment of the present disclosure, when the first, second, third, and fourth electronic modules EMa, EMb, EMc, and EMd do not overlap with the base substrate BLd, positions of the first, second, third, and fourth electronic modules EMa, EMb, EMc, and EMd may be changed depending on the cutting tolerance of the base substrate BLd. In this case, the openings are required to be sufficiently spaced apart from the active area AA by taking into account the cutting tolerance which is essentially applied at the outer edge of the base substrate BLd, and this may cause an increase in the dimension of the bezel especially as a distance measured from the active area AA.

However, according to one or more exemplary embodiment of the present disclosure, the first, second, third, and fourth electronic modules EMa, EMb, EMc, and EMd may overlap with the base substrate BLd. That is, the positions of the first, second, third, and fourth electronic modules EMa, EMb, EMc, and EMd are disposed within a planar dimension of the base substrate BLd and may not be affected by the cutting tolerance which is essentially applied to the outer edge of the base substrate BLd. Accordingly, the dimension of the bezel may be reduced since the cutting tolerance affecting a planar dimension of the base substrate BLd is not a consideration when determining the position of the openings relative to an outer edge of the base substrate BLd.

FIG. 11 is an enlarged plan view illustrating another modified exemplary embodiment of portion AA′ shown in FIG. 4A.

Referring to FIG. 11, a base substrate BLe may include a first base portion BL1, a second base portion BL2b, a third base portion BL3, a fourth base portion BL4, and a fifth base portion BL5.

The second base portion BL2b, the third base portion BL3, the fourth base portion BL4, and the fifth base portion BL5 may each protrude from the first base portion BL1. In an exemplary embodiment, for example, the second base portion BL2b, the third base portion BL3, the fourth base portion BL4, and the fifth base portion BL5 may each protrude from a same one of the first side FS of the first base portion BL1. The second base portion BL2b, the third base portion BL3, the fourth base portion BL4, and the fifth base portion BL5 may be spaced apart from each other along the first direction DR1.

The first electronic module EMa, the second electronic module EMb, the third electronic module EMc, and the fourth electronic module EMd may be disposed under the second base portion BL2b, the third base portion BL3, the fourth base portion BL4, and the fifth base portion BL5, respectively.

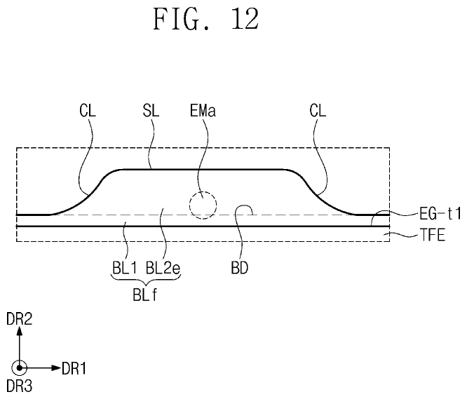

FIG. 12 is an enlarged top plan view illustrating an exemplary embodiment of a base substrate relative to other components of a display panel.

Referring to FIG. 12, a base substrate BLf may include a first base portion BL1 and a second base portion BL2e. The second base portion BL2e may protrude from the first base portion BL1. An outer edge of the base substrate BLf at a side of the display device DD at which an electronic module (e.g., first electronic module EMa) is disposed, may include the second base portion BL2e defined by a straight line SL (e.g., straight line portion SL) lengthwise extending along the first direction DR1 and a curved lines CL (e.g., curved line portion CL) provided in plurality (e.g., curved lines CL or curved lines portions CL) respectively extended from opposing ends of the straight line SL. The curved lines CL may connect the straight line SL and the first base portion BL1 to each other.

A boundary BD between the first base portion BL1 and the second base portion BL2e may lengthwise extend along the first direction DR1. The first electronic module EMa may be disposed under both the first base portion BL1 and the second base portion BL2e. The first electronic module EMa may overlap with the boundary BD when viewed in a plan view. Therefore, the first electronic module EMa may overlap with the first base portion BL1 and the second base portion BL2e.

An edge EG-t1 of the encapsulation layer TFE may be spaced apart from the boundary BD along the second direction DR2. In an exemplary embodiment, for example, the edge EG-t1 may overlap with the first base portion BL1 when viewed in a plan view. In addition, the edge EG-t1 of the encapsulation layer TFE may not overlap with the first electronic module EMa when viewed in a plan view.

Although exemplary embodiments of the present disclosure have been described, it is understood that the present disclosure is not limited to these exemplary embodiments but various changes and modifications can be made by one ordinary skilled in the art within the spirit and scope of the present disclosure as hereinafter claimed. Therefore, the disclosed subject matter is not limited to any single embodiment described herein, and the scope of the invention shall be determined according to the attached claims.

What is claimed is:

1. A display device comprising:
a display area and a non-display area adjacent to each other;
a base substrate comprising at a same side thereof:
a first base portion corresponding to the display area and having a first width along a first direction, and
a second base portion which protrudes from the first base portion along a second direction crossing the first direction, the second base portion corresponding to the non-display area and having a second width along the first direction which is smaller than the first width;
a display element layer disposed on the first base portion of the base substrate;
an encapsulation layer which encapsulates the display element layer on the base substrate; and
an electronic module which receives input from outside the display device or provides output from the display device to outside thereof, the electronic module corresponding to the second base portion and overlapped by the second base portion along a thickness direction of the display device which crosses each of the first direction and the second direction.

2. The display device of claim 1, wherein
the electronic module is provided in plural as a plurality of electronic modules arranged along the same side of the base substrate, and
a same one of the second base portion corresponds to and overlaps each of the plurality of electronic modules.

3. The display device of claim 1, wherein
the electronic module is provided in plural as a plurality of electronic modules arranged along the same side of the base substrate, and
the plurality of electronic modules comprises:
a first electronic module corresponding to the second base portion and overlapped by the second base portion along the thickness direction of the display device, and
a second electronic module different from the first electronic module, disposed spaced apart from an outer edge of the base substrate which is defined by the first base portion and the second base portion.

4. The display device of claim 1, wherein along the thickness direction of the display device, a thickness of the first base portion is equal to a thickness of the second base portion.

5. The display device of claim 1, wherein along the thickness direction of the display device, the first base portion has a first thickness and the second base portion has a second thickness which is smaller than the first thickness.

6. The display device of claim 1, wherein the electronic module which corresponds to the second base portion and is overlapped by the second base portion along the thickness direction of the display device is visible from outside the display device.

7. The display device of claim 1, wherein the electronic module is further overlapped by the first base portion along the thickness direction of the display device.

8. The display device of claim 1, wherein
the base substrate comprises a third base portion which protrudes from the first base portion along the second direction, has a width along the first direction which is smaller than the first width, and is spaced apart from the second base portion along the first direction,
the electronic module is provided in plural as a plurality of electronic modules arranged along the same side of the base substrate, and
the plurality of electronic modules comprises:
a first electronic module corresponding to the second base portion and overlapped by the second base portion along the thickness direction of the display device, and
a second electronic module different from the first electronic module, corresponding to the third base portion and overlapped by the third base portion along the thickness direction of the display device.

9. The display device of claim 1, wherein
the encapsulation layer corresponds to the first base portion, and
at the same side of the base substrate, an outer edge of the encapsulation layer is spaced apart from the second base portion along the second direction.

10. The display device of claim 1, wherein the encapsulation layer comprises:
a first encapsulation portion corresponding to the first base portion of the base substrate, and
a second encapsulation portion correspond to the second base portion of the base substrate.

11. The display device of claim 10, wherein along the thickness direction of the display device, a thickness of the second encapsulation portion decreases as a distance along the second direction from the first base portion increases.

12. The display device of claim 1, wherein along a plane defined by the first direction and the second direction, an outer edge of the second base portion has a curvature.

13. The display device of claim 1, wherein in a plane defined by the first direction and the second direction, the second base portion has a polygonal shape.

14. A display device comprising:
a display area and a non-display area adjacent to each other;
a display panel comprising:
a base substrate comprising: a first base portion corresponding to the display area, and a second base portion which protrudes from a first side of the first base portion and corresponds to the non-display area,
along the first side, a boundary is defined between the first base portion and the second base portion, a length of the boundary being smaller than a length of the first side,
a display element layer disposed on the first base portion of the base substrate, and
an encapsulation layer which encapsulates the display element layer on the base substrate; and
an electronic module which receives input from outside the display device or provides output from the display device to outside thereof, the electronic module corresponding to the second base portion and visible from outside the display device.

15. The display device of claim 14, wherein an outer edge of the encapsulation layer corresponds to the boundary between the first base portion and the second base portion.

16. The display device of claim 14, wherein
the encapsulation layer comprises a first encapsulation portion corresponding to the first base portion of the base substrate and a second encapsulation portion corresponding to the second base portion of the base substrate,
along a direction from the first base portion to the second base portion, the second encapsulation portion has a thickness which decreases as a distance from the first base portion increases, and
a light transmittance area of the display panel is defined including a planar area of the second base portion which corresponds to the electronic module and, a light transmittance of the light transmittance area is equal to or greater than about 90%.

17. The display device of claim 14, wherein a thickness of the first base portion is greater than a thickness of the second base portion.

18. The display device of claim 14, wherein the electronic module overlaps with the boundary between the first base portion and the second base portion.

19. The display device of claim 18, wherein at the first side, an outer edge of the encapsulation layer is spaced apart from each of the electronic module and the boundary between the first base portion and the second base portion.

20. The display device of claim 14, wherein at the first side, an outer edge of the second base portion has a curvature or the second base portion has a polygonal shape in a top plan view.
